(19) United States
(12) Patent Application Publication
(10) Pub. No.: US 2024/0237538 A1
(43) Pub. Date: Jul. 11, 2024

(54) POSITIONING DEVICE AND METHOD FOR OPERATING SUCH A POSITIONING DEVICE

(71) Applicant: PHYSIK INSTRUMENTE (PI) GMBH & CO. KG, Karlsruhe (DE)

(72) Inventor: Alexej WISCHNEWSKI, Worth (DE)

(21) Appl. No.: 18/561,928

(22) PCT Filed: May 17, 2022
(86) PCT No.: PCT/DE2022/100369

§ 371 Date: Nov. 17, 2023

(30) Foreign Application Priority Data
May 18, 2021 (DE) 10 2021 112 809.9

(51) Int. Cl. H10N 30/00; G01H 11/08; H10N 30/02; H10N 30/80

(52) U.S. Cl. CPC H10N 30/1071; G01H 11/08; H10N 30/02; H10N 30/802

(57) ABSTRACT

The invention relates to a positioning device (1) comprising a positioning unit (2) having at least one piezoelectric actuator (4), a drive element (5) to be coupled with an element (6) to be positioned, and a controller (3). The positioning device has a defect analysis device (16) for detecting defects in the positioning unit (2), wherein the actuator (4) or actuators, in addition to functioning as a drive for the drive element (5), functions or function as a generator (12) or a receiver (13) of ultrasonic sound waves, and the defect analysis device (16) comprises a measurement signal generator (22) for generating a sinusoidal electrical voltage for exciting the or a generator (12) and a resonance analyser (24) for analysing an electrical signal generated by the or a receiver (13). The invention also relates to a method for operating such a positioning device in order to detect defects in the positioning unit (2).

The invention relates to a positioning device according to claim 1 and a method of operating such a positioning device according to claim 14.

Piezoelectrically driven positioning devices enable fine positioning in ranges from a few tenths of a picometer to several centimeters. In particular, piezoelectric multilayer actuators are used as adjustment members in these mechanical systems. Piezoelectric actuators are electromechanical energy converters whose operating principle is based on changes in the shape of certain crystals under the influence of an electric field. The actuators consist of piezoelectric single crystals, piezoelectric monocrystalline ceramics or piezoelectric polymer composites.

Piezoelectrically driven positioning devices are used, among other things, in highly complex and therefore cost-intensive equipment, for example in lithography machines or optical star telescopes. Although the multilayer actuators operate predominantly quasistatically. i.e. far below the lowest resonance of the system; they are nevertheless exposed to constant mechanical stress, as are the solid-state joints usually used in such positioning devices, via which the feed of the element to be driven is realized by their elastic deformation. The contraction and expansion of the actuator or the bending of the solid-state joints can occur up to 20,000 times per second during operation. With increasing operating time, micro-cracks, short circuits, delaminations or other defects can occur in the actuators, guides, joints or other components of the micropositioning device, which can negatively affect the operation of the device up to a total failure. A sudden failure of the positioning device usually causes high costs.

Most of the aforementioned defects do not normally occur suddenly, but develop over time, starting from only a minor initial defect, and then propagate. Every mechanical system has a specific resonance pattern, which depends on the shape, geometric dimensions, material properties, etc. of individual system components. Defects cause a change in the resonance pattern of a system. The emergence of resonances that were not previously present or a change or elimination of resonances previously present in the system indicate the emergence of defects.

A method for the non-destructive measurement of material properties of an object by means of ultrasonic waves is known from U.S. Pat. No. 3,720,098. For this purpose, ultrasonic waves are induced into the object to be examined with the aid of a transmitter and their propagation time is measured with the aid of a receiver. By analyzing the ultrasonic wave propagation in the object, conclusions about its material properties are obtained.

The scientific article ‘Rapid Nondestructive Testing of Ceramic Multilayer Capacitors’ by O. Boser, P. Kellawon, R. Geyer in IEEE Transactions on Components, Hybrids and Manufacturing Technology, Vol. 12, No. I, 1989 describes a method for nondestructive detection of cracks, delaminations or other defects in a multilayer piezoceramic capacitor. The method is based on the excitation of standing ultrasonic waves in the capacitor. The recording of the impedance of the capacitor is performed using a laboratory impedance analyzer HP Model 4192A. It is shown that a change in the impedance image of a multilayer capacitor is evidence of an internal defect in the capacitor.

From the scientific article ‘Impedance Spectroscopy of Piezoelectric Actuators' by C. R. Bowen, M. Lopez-Prieto, S. Mahon, F. Lowrie in: Scripta mater, 42 (2000), 813-818, a method for the non-destructive detection of cracks, delaminations or other defects in a multilayer piezoelectric actuator is known. The change in the resonance pattern of the actuator due to the internal defects is investigated. For this purpose, an impedance spectrum of the actuator is compared with the direct measurements using an optical as well as a scanner electron microscope. The recording of the impedance is performed using a laboratory impedance analyzer (Solartron 1260) from below to above the actuator resonance. It is confirmed that by examining the impedance of the multilayer piezoelectric actuator, it is possible to detect defects within the actuator quickly and non-destructively.

US2010/0013352 A1 describes a system for analyzing and suppressing unwanted vibrations in various machines, for example turbines, motors or robots. The system includes a number of piezoelectric vibration sensors, actuators for generating vibrations, and a controller connected to the sensors as well as actuators. The measured vibrations are transmitted to the controller by means of a feedback loop, which then dynamically changes the drive signal for the actuators. To suppress the unwanted vibrations, the controller drives the actuators according to a vibration suppression algorithm.

A device for non-destructive detection of structural damage is known from EP 1 735 586 B1. The device includes a piezoelectric sensor and an actuator. The actuator generates acoustic waves in the structure under investigation. The sensor receives the waves reflected from the structure. An evaluation of the sensor signal indicates the presence of structural damage.

The object of the invention is to provide a positioning device in which it is possible to predict or detect defects arising within the positioning unit, and to provide a method for operating such a positioning device in order to predict or detect defects within the positioning unit. This enables in particular a timely replacement of corresponding components of the positioning unit before it comes in the worst case to its total failure.

The positioning device according to the invention comprises a positioning unit as well as a controller. The positioning unit in turn comprises at least one piezoelectric and preferably multilayer actuator, which serves to move a drive element, the movement of the drive element being caused by targeted mechanical deformations of the at least one actuator and the movement of the drive element being provided for driving or positioning an element to be positioned.

A coupling between the drive element and the element to be positioned is provided for transferring the movement of the drive element to the element to be positioned. This coupling can, for example, be a rigid mechanical connection, so that there is a direct conversion of the movement of the drive element to the element to be positioned. However, the coupling can also be implemented as a frictional contact and, in particular, as an intermittent frictional contact between the drive element and the element to be positioned, in which a frictional or frictional contact is present between the drive element and the element to be positioned at times, i.e. during a drive step, and a mechanical coupling via a frictional or frictional contact is present during this time interval. A respective drive step is then followed in time by a phase in which the drive element returns to an initial position, whereby the next drive step is prepared.

In the case that the positioning unit comprises a single actuator, this actuator, in addition to its drive function, is designed or arranged to act or function both as a generator and as a receiver of acoustic ultrasonic waves. In the case that the positioning unit has several, i.e. at least two, actuators, at least one of the actuators is designed to act or function at least as a generator of acoustic ultrasonic waves, and at least one other of the actuators is designed to act or function at least as a receiver of acoustic ultrasonic waves.

In other words, the positioning device according to the invention or its positioning unit either has only one piezoelectric and preferably multilayer actuator, which then, in addition to its function of moving the drive element, simultaneously functions as a generator and as a receiver of acoustic ultrasonic waves and thus combines the functions as a drive, generator and receiver in itself, or else that the positioning device or the positioning unit has several, i.e. at least two, piezoelectric and preferably multilayer actuators, of which either only one, or several or all, in addition to the function of moving the drive element, simultaneously functions as a generator and as a receiver of acoustic ultrasonic waves. In addition, it is possible that in the case that the positioning device or the positioning unit comprises several actuators, one or more of the actuators, in addition to the drive function, only functions as a generator of acoustic ultrasonic waves, and another actuator or several other actuators, in addition to the drive function, only functions as a receiver of acoustic ultrasonic waves, so that the functions of drive plus generator and drive plus receiver are divided between at least two different and spatially separate actuators.

When subsequent portions of the description or the claims refer to “or ‘the actuator’ (i.e., singular), this is not to be understood restrictively to a single actuator. Rather, the use of the singular in connection with the term” (i.e., ‘an actuator’ or ‘the actuator’) is to be understood or construed to mean that the features related to the actuator either apply only to the single actuator, or, in the case of multiple actuators, apply to all or only some of them or only one of them. If, for example, an arrangement of an actuator is described, then this arrangement description applies either, i.e. in the case of the presence of a single actuator, to just this single actuator, or, i.e. in the case of the presence of several actuators, to one of the actuators, to all of the actuators, or else to only some of the actuators, or else to only one of the actuators. The foregoing applies identically to the use of the terms ‘a generator’ and ‘a receiver’ herein.

The term ‘or’ used herein, unless explicitly stated otherwise, is to be understood as an inclusive Or. i.e., a non-exclusive disjunction. In this context, for example, the term ‘the actuator’ has the function of a generator or a receiver is to be understood herein as meaning that the actuator has the function of a generator or the function of a receiver, or else that the actuator has the function of a generator and a receiver.

The function of the mechanical adjustment member in the positioning unit is performed by the actuator or actuators, whereby the number of actuators used is primarily determined by the application. In addition to the function of an adjustment member, when a single actuator is present, it has—in addition to its drive function—both the function of a generator and that of a receiver of acoustic ultrasonic waves. In this case, i.e. in the presence of a single actuator, it includes both the generator and the receiver of ultrasonic acoustic waves. The function of the generator is to generate ultrasonic acoustic waves, while the function of the receiver is to receive the ultrasonic acoustic waves.

The actuator is arranged, for example, between solid-state joints and is connected or coupled to the drive element via the latter. The movement or deformation of the actuator is transmitted to the drive element by elastic deformation of the solid-state joints.

In the case of a multilayer actuator, the actuator is composed of several layers, each layer consisting of two electrodes as well as a polarized piezoelectric material arranged between the electrodes. In this context, one also speaks of a multilayer actuator.

The controller comprises a presetting-regulation controller of the actuator or positioning unit, a defect analysis device from which the generator of acoustic ultrasonic waves is excited and from which the signal of the receiver of acoustic ultrasonic waves is recorded and analyzed, and optionally a commutator. In the optional commutator, switching takes place between actuator operation (i.e., to generate motion or deformation of the actuator) and sensor operation of the actuator as a generator or as a receiver. In addition, the controller may interface with a computer having a display screen on which defect analysis can be performed visually by a person.

The presetting-regulation controller includes a power output stage for the actuator, a trajectory and signal generator, a position controller for controlling the position and optionally the speed or acceleration of the positioning unit.

The defect analysis device has the functions of controlling and/or regulating the actuator or positioning unit, exciting the or a generator of ultrasonic acoustic waves with a measurement signal, and processing the signal coming from the or a receiver of the ultrasonic acoustic waves. The defect analysis device comprises at least one measurement signal generator for generating an electrical sinusoidal voltage and a resonance analyzer for analyzing a signal generated by an actuator acting as a receiver.

The piezoelectric material for the actuator may be a monocrystalline piezoelectric material, a polycrystalline piezoelectric ceramic, a piezoelectric polymeric material, or other piezoelectric or electrostrictive material. The positioning unit may include one or more, preferably multilayer, actuators. If solid-state joints are used in the positioning unit, they may be flexure or torsion joints.

The actuator is connected to the controller for exciting the generator as well as for processing the signals received from the receiver of acoustic ultrasonic waves.

The use of an actuator in the positioning unit not only as an adjustment member, but also as a generator or as a receiver of acoustic ultrasonic waves, gives the positioning unit qualitatively completely new properties. This avoids the costly installation of additional discrete transmitters and receivers. The probability of failure of the positioning unit or the positioning device is increased due to the absence of additional system components.

The resonance analyzer processes the signal coming from the current sensor, stores it and the signal from the measurement generator, and compares or analyzes two recorded resonance signals or resonance spectra with each other. For comparing or analyzing efficiently appropriate neural network algorithms are used. When defined deviations are detected in the analyzed resonance images, a visual or other warning is issued. The data is also transmitted from the resonance analyzer to the screen of a computer via the optional interface. An operating person or operator can perform visual analysis or inspection of measurement data if necessary.

An advantageous embodiment of the positioning device according to the invention provides that the measurement signal generator is designed to generate an electrical sinusoidal voltage with a periodic frequency sweep. This allows the positioning unit to be excited periodically in a specific range, so that a resonance image is generated in a defined frequency range, which can be analyzed.

Another advantageous embodiment of the positioning device according to the invention provides that the defect analysis device includes a linear or clocked broadband output voltage or current amplifier, which appropriately amplifies the signal generated by the measurement signal generator for the excitation of the generator in the necessary frequency range. In addition, it may be advantageous that the defect analysis device uses as output voltage or current amplifier for the measurement signal generator the same power output stage that is used to drive the actuator from the closed-loop control controller.

It may be advantageous that the defect analysis device comprises a white noise generator, and it may be particularly advantageous that the measurement signal generator is suitable for generating this white noise. The white noise includes a broad spectrum of frequencies with a constant power density spectrum in a defined frequency range. The signal may advantageously be used as a broadband and efficient excitation of the positioning unit to obtain its resonance image.

In addition, it may be advantageous that the position controller or the trajectory and signal generator of the controller are implemented by means of an integrated circuit, for example in the form of a digital signal processor (DSP) or a field programmable gate array (FPGA), and the measurement signal generator and the resonance analyzer are implemented as a program module in the same integrated circuit. Especially in cost-sensitive applications, it is advantageous to accommodate the functions of the defect analysis device in the same integrated circuit that is already used for the control or regulation tasks of the positioning unit.

Furthermore, it may be advantageous for the resonance analyzer to include a data interface to a monitor for visual inspection of a resonance image. In this case, the data is transmitted from the resonance analyzer to the monitor of a computer via an interface. An operator can perform visual analysis or inspection of measurement data when necessary.

Furthermore, it may be advantageous that the defect analysis device comprises a current sensor for detecting a signal generated by an actuator or by a receiver. The electric current flowing through the actuator or through the receiver includes the information about the resonance image of the positioning unit or the positioning device. The current sensor converts the current generated by the receiver into an electrical voltage U′i, amplifies it and makes it available to the resonance analyzer. The current conversion can be done by means of a resistor with a subsequent amplification, or by a transistor, transformer or operational amplifier. An optocoupler can also be used advantageously for this purpose. When using an optocoupler or transformer, the actuator is advantageously galvanically isolated from the defect analysis device.

In addition, it may be advantageous to have at least one generator or receiver located between solid state joints. The arrangement of the generator and the receiver of acoustic ultrasonic waves between solid-state joints such as flexure joints, torsion joints or flexure joint guides enables their better acoustic aging. During excitation or reception of ultrasonic acoustic waves, the generator as well as the receiver are less stressed on the part of surrounding mechanical parts. Their oscillation in the ultrasonic range is thus less affected. The mechanical quality of these mechanical oscillating circuits is thus increased, and less power is required for excitation of the generator. The sensitivity of the receiver is also increased as a result.

It may be advantageous here that the movement of the drive means is guided by the solid-state joints between which the generator or the receiver is arranged, or by additional solid-state joints of the positioning unit.

In addition, it can be advantageous that the coupling of the drive element to an element to be positioned is realized via a fixed connection or via a friction contact. A positioning unit in which the movement or deformation of the actuator is transmitted via the drive element to the element to be positioned by means of a frictional contact enables qualitative control of the frictional contact of the positioning unit. Thus, a deterioration of the frictional contact due to any contamination of the friction pair can be detected directly with the acoustic analysis. Likewise, delamination of a friction rail, with which the drive element is or comes into frictional contact, of the element to be positioned can be detected. In the case of a fixed connection between the drive element and the element to be positioned, the movement of the drive element is directly transferred to the element to be positioned, which can take place extremely precisely and with high resolution, although a comparatively short travel distance is possible due to the limited deformation of the actuator.

Furthermore, it may be advantageous that a generator or a receiver is formed from at least a portion of an actuator. In case of a multilayer actuator, at least a part of the layers of the actuator forms a generator or a receiver. By partially or regionally stressing or using the piezoelectric material for a generator or a receiver, a better acoustic matching of ultrasonic acoustic waves to the mechanical environment can be achieved. In the case of a multilayer actuator, for example, only one layer or about half of all layers can be used for a generator or a receiver. In this case, the layers are electrically connected accordingly and electrical lines relating to this are routed out of the positioning unit. The activation of the actuator and the generator as well as the transfer of the signal from the receiver take place in the controller.

In this regard, it may prove advantageous that the generator or receiver formed by at least a portion of the actuator has no actuation function, i.e., no function causing a deformation or movement, and is connected to the remaining portion of the actuator by an acoustic connection with a low acoustic resistance. By the resulting separation of the generator or receiver from acoustic ultrasonic waves, a structure can be realized that can be used independently of the actuator function.

It may also be advantageous to use a generator of one actuator and a receiver of another actuator to detect defects in the positioning unit. Thus, in a positioning unit with multiple actuators, a generator of acoustic ultrasonic waves of one actuator and a receiver of another actuator can be used. By the spatial separation, i.e., by spacing, of the generator and receiver of acoustic ultrasonic waves given by this, the transit time measurement of an acoustic measurement signal pulse can be realized. The time-of-flight measurement of the acoustic signal represents a further method for detecting resonances or defects in the positioning unit.

The invention also relates to a method of operating the positioning device described above to predict or detect defects arising in the positioning device or in its positioning unit.

Each component of the positioning unit represents a mechanical oscillator that has a resonance determined by its dimensions, material properties, as well as the method of installation. Cracks in components of the positioning unit, delaminations in the multilayer structure of a multilayer actuator, material fatigue in solid-state joints as well as other defects of the positioning unit lead to changes in its acoustic image. New resonances are created, existing resonances change or even disappear.

The method according to the invention provides that the actuator, in addition to functioning as an adjustment member, i.e., generating a movement of the driving element serving to position an element to be positioned due to a deformation of the actuator, is also used or operated to function as a generator or a receiver of ultrasonic acoustic waves, said ultrasonic acoustic waves being used to detect defects in the positioning unit.

For this purpose, an electrical measurement signal from the measurement signal generator of the defect analysis device is periodically applied to the or an actuator. The measurement signal may be an AC electrical voltage or an AC current. The actuator or the generator excites acoustic ultrasonic waves in the entire positioning unit, which are periodically recorded as mechanical resonances of the entire positioning unit as well as of the actuator itself by the actuator or receiver and are made available to the resonance analyzer for processing. The resonance analyzer processes the signal coming from an optional current sensor and stores it as well as the signal from the measurement signal generator.

In a further step, the resonance analyzer compares or analyzes two recorded signals or resonance spectra of the positioning unit with each other. During this comparison, the resonances that were previously present and have now disappeared or changed are detected, and newly created resonances are registered. Appropriate efficient neural network algorithms are used for comparison or analysis. If defined deviations are detected in the analyzed resonance images, a visual or other warning is issued.

The method according to the invention for predicting and detecting defects in the positioning unit according to the invention as well as its components enables automatic monitoring of the condition of the positioning unit and timely replacement or maintenance when defects occur. The use of a piezoelectric actuator in the positioning unit not only as an adjustment member, but also as a generator or receiver of ultrasonic acoustic waves gives the positioning unit qualitatively quite new properties. The positioning device according to the invention or the corresponding method according to the invention saves in particular a cost-intensive installation of additional discrete transmitters and receivers.

In the method, either a DC electric voltage or a low-frequency AC electric voltage is applied to the or an actuator by a power output stage, or a high-frequency AC electric voltage is applied to the or an actuator by an amplifier. In this context, low-frequency means a voltage whose frequency is at least three times lower than the frequency of the lowest resonance of the positioning unit. In this context, high-frequency means that the frequency of the voltage is nearly equal to or higher than the lowest resonance frequency of the positioning unit. When an electric voltage is applied to the piezoelectric material of the actuator, the latter undergoes an expansion or a contraction depending on the voltage sign, and thereby performs a positioning function, i.e. it transfers this expansion or contraction to the drive means connected to it, which in turn is provided for coupling with an element to be positioned, and via this coupling a positioning movement of the element to be positioned can be achieved.

In addition to the adjustment member function, the actuator or a part thereof has the function of a generator or a receiver of ultrasonic acoustic waves. When a measurement signal from an amplifier is applied to a generator, ultrasonic acoustic waves are excited in its vicinity or in the positioning unit and are received by a receiver and converted into an electric current. The current flowing through the actuator reaches the optional current sensor, is converted by it into an electrical voltage Ui and is further processed by the resonance analyzer.

It may be advantageous that the detection of the newly created resonances or the disappearance or change of the previously existing resonances is performed by forming the magnitude of the electrical impedance |Z| of the positioning unit as a function of the frequency. For this purpose, the frequency of the measurement signal voltage U_{MG} is changed according to a frequency sweep from an initial value f_{A} to a final value f_{E}, and the current value I_{A} flowing through the receiver and the phase angle value φ between the current and the voltage U_{A} are measured as a function of the frequency and recorded together with the voltage. From the series of measurements, the variation of the impedance value |Z|=U_{A}/I_{A} as a function of frequency is formed to detect resonances. Then, from the impedance variation Z (|Z|=f(f) and the variation φ(f), the resonance analyzer determines the presence of new mechanical resonances or the absence of previously existing ones.

All resonances of the positioning unit are included in the impedance curve. The occurrence of defects in system components of the positioning unit causes an emergence of new resonances in the positioning unit or a change of the previously existing resonance pattern. These changes are easily recognizable in the impedance curve. They can be advantageously identified in the resonance analyzer using pattern recognition neural network algorithms.

It can also be advantageous that during the frequency sweep the current value flowing through the receiver as well as the phase angle value between the current and the voltage are measured in the form of a dependence on the frequency and recorded together with the voltage, whereby from the series of measurements for the detection of resonances the impedance magnitude |Z| as well as the phase angle f are represented in a Nyquist diagram. The Nyquist diagram allows a particularly advantageous representation of the frequency image of the positioning unit due to a simultaneous representation of the magnitude of the impedance with the phase angle.

Moreover, it may be advantageous that in the frequency sweep, the initial frequency value of the measurement signal is equal to or slightly smaller than the lowest measurable resonance frequency value of an actuator, and the final resonance frequency value of the measurement signal is equal to or slightly larger than the resonance frequency value of the highest measurable resonance of an actuator, wherein both the lowest resonance frequency value and the highest resonance frequency value may belong to the different types of ultrasonic acoustic waves, for example the longitudinal, bending, radial, shear or other vibration modes of the actuator.

The preferably multilayer piezoelectric actuator is an essential component of the positioning unit of the positioning device. The actuator has specific eigenmodes as well as associated eigenresonances. The eigenresonances of the actuator can be identified before installation in the positioning unit. After installation, they are contained in the resonance image of the positioning unit when excited and can also be identified. By exciting the positioning unit in the frequency range of the resonance frequencies of an actuator, defects in this actuator are specifically detected.

Further, in the frequency sweep, it may be advantageous for the initial frequency value of the measurement signal to be equal to the lowest resonant frequency value of an actuator determined by its length, and for the final frequency value of the measurement signal to be equal to twice the resonant frequency value determined by half the actuator length.

The actuator is usually subjected to particularly strong longitudinal expansion during operation. This type of stress often causes cracks between the individual layers and delamination in the case of a multilayer actuator. Excitation and resonance analysis of the positioning unit in the frequency range of the longitudinal and flexural vibration modes of the actuator can be used to specifically detect this type of defect.

Moreover, in the frequency sweep, it may be advantageous that the frequency of the electrical measurement voltage is changed from the initial value to the final value logarithmically or according to another expedient function. This makes it possible to perform a quick defect test of the positioning unit or to adjust the detection of the resonances of a positioning unit with a certain acoustic image.

Furthermore, it may be advantageous that the measurement signal is white noise and the current flowing through the actuator is measured and recorded. Then, for the purpose of detecting resonances, the measurement series is subjected to a Fourier transform, a discrete Fourier transformation (DFT), or a fast Fourier transformation (FFT). Newly created, disappeared or changed resonances are detected. Fourier transforms can be efficiently implemented in a DSP or an FPGA and enable fast analysis execution. With the result of a Fourier transform, resonances are easily recognizable as amplitudes, so that the detection of change in the resonance image of the positioning unit can also be performed efficiently.

Furthermore, it may be advantageous that the frequency value of the measurement signal is equal to a measurable resonance frequency value of the actuator, wherein the resonance may belong to the various types of ultrasonic acoustic waves, for example the longitudinal, bending, radial, shear or other vibration modes of the actuator, and after a short excitation of a generator at this resonance frequency, the decay of the positioning unit is recorded by means of a receiver, and further for detecting a resonance change, the recorded decay curve is compared with the decay curve recorded at an earlier time.

The electric current of a positioning unit driven by a piezoelectric actuator decays after the actuator is pushed or excited on a resonance approximately according to the function I=I₀ EXP(−λt)sin(ωt), where I is the current, I₀ is the initial current, λ is the decay constant, ω is the angular frequency, and t is the time. When one of the resonances changes due to a defect, this change can be detected by the decay behavior or in the change of the amplitude decay function Aᵢ=I₀ EXP(−λt), the decay time or the frequency of the decaying oscillation. The decay time as well as decay function of the oscillation can be recorded quickly and easily by a microprocessor-based measuring device. The defects arising in the actuator can be detected by comparing decay curves.

It may be advantageous that the frequency value of the measurement signal is equal to a measurable resonance frequency value of the positioning unit, wherein after a short excitation of a generator, the decay behavior of the positioning unit is recorded for the purpose of detecting a resonance change and compared with a decay behavior recorded at an earlier time. By observing the change in specific resonances of the positioning unit, defects in its components or structural parts can be detected.

It may also be advantageous that the frequency value of the measurement signal is equal to a measurable resonance frequency value of the positioning unit, wherein during excitation of a generator for the purpose of detecting a resonance change, the internal resistance RFᵢ=U_{A}/I_{A}, of the positioning unit is determined and compared to an internal resistance recorded at an earlier time.

When defects occur in the positioning unit, some previously existing resonances are changed. The resonance curve of a mechanical oscillator is characterized by its loss resistance R_{V}, referred to here as the internal resistance Rᵢ. Each resonance of the positioning unit represents an oscillator that has an internal resistance Rᵢ. Rᵢ is changed by arising defects. The internal resistance Rᵢ, can be determined by recording the electrical voltage at the actuator U_{Ar} as well as the current through the actuator r at a defined resonance frequency fᵣ. The recording of the voltage U_{Ar} and the current I_{Ar} can be easily realized and quickly analyzed by a microcontroller based measuring device.

It may be further advantageous that the frequency value of the measurement signal is equal to a measurable resonance frequency value of the positioning unit, wherein during or after excitation of a generator for the purpose of detecting a resonance change, the reflected pulse is picked up by a receiver and its parameters are compared with those of a previously picked up reflected pulse.

The transit time, amplitude, or shape of the reflected pulse may be used to detect defects. The ultrasonic pulse can be transmitted by a generator of one actuator and received by a receiver of another actuator. Detecting the resonance change of the positioning unit by exciting a short pulse and evaluating parameters of a reflected pulse enables quick defect identification of the positioning unit. In this case, the measurement signal can contain several pulses. The pulses can also be amplitude or phase modulated.

It may also be advantageous that the detection of resonances and the defect analysis are performed in the normal operating mode of the positioning unit. In this case, the resonance image of the positioning unit is recorded once during the initial start-up and then further periodically or repeatedly during normal operation. The measurement recordings are compared with the first recording and analyzed. This makes it possible to observe the condition of the positioning unit without interrupting its operation.

Furthermore, it may be advantageous that the analysis of the recorded resonance image can be performed visually by an operator. In this way, it is possible to enable intervention by a person in the event of non-unique resonance images, or to initiate replacement of the defective positioning unit or defective components thereof. For this purpose, the device according to the invention may include a computer with a screen or monitor.

Further details, advantages and features of the invention will be apparent from the following description and drawings, to which express reference is made with respect to all details not described in the text. Showing;

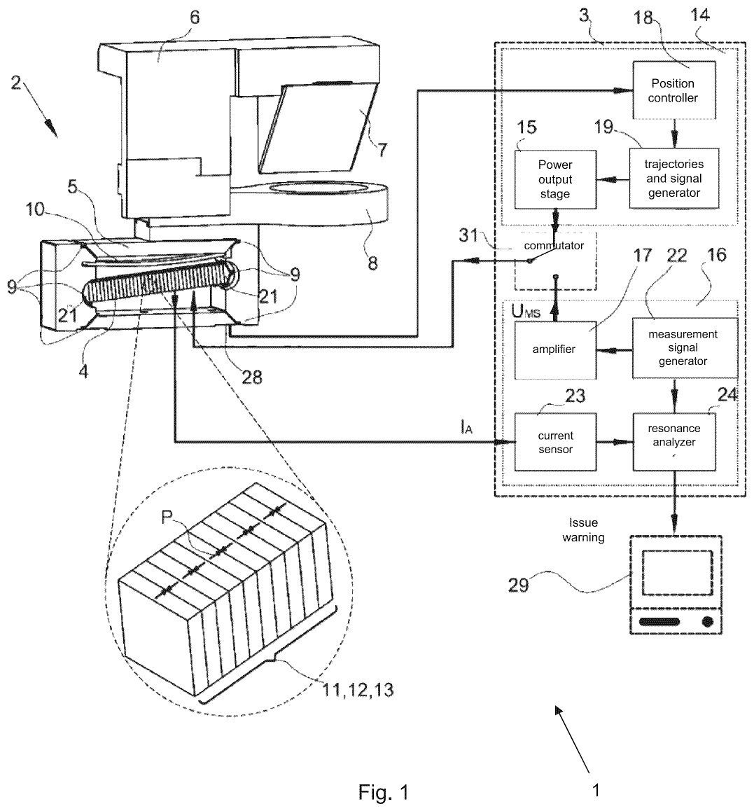

FIG. 1: Schematic representation of a positioning device according to the invention.

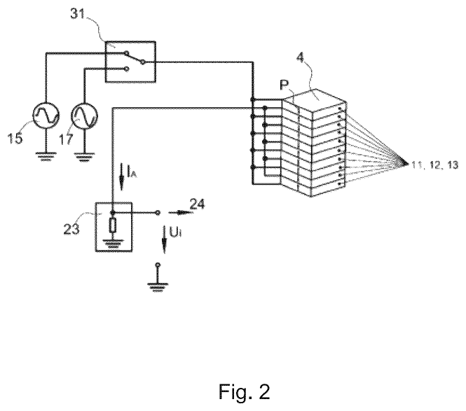

FIG. 2: Schematic diagram of an embodiment of a piezoelectric multilayer actuator of a positioning unit with a generator and a receiver of ultrasonic acoustic waves.

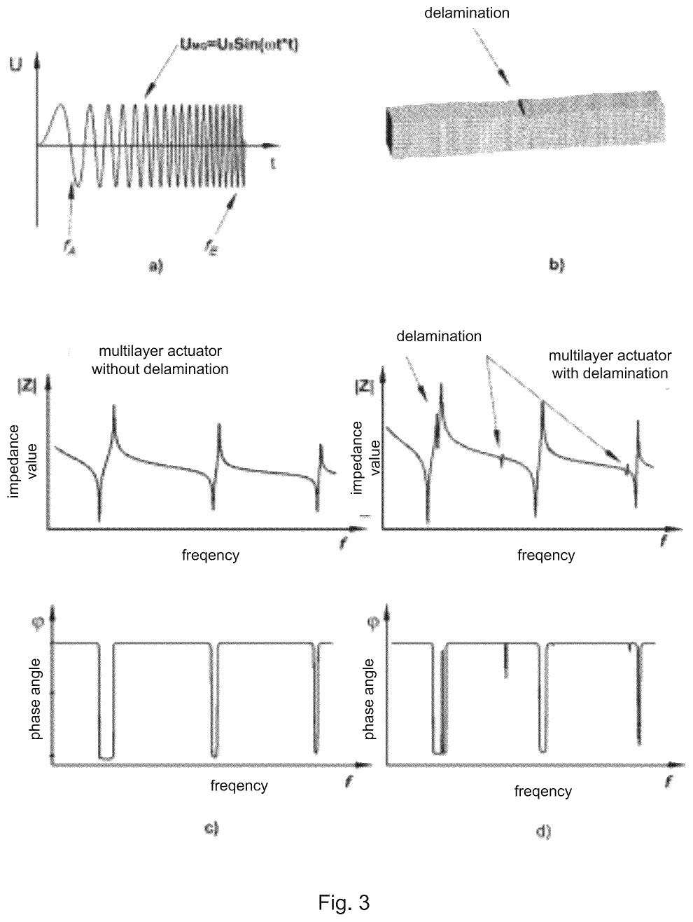

FIG. 3: a) Voltage of the measuring signal generator U_{MG} with a variable frequency; b) FEM model of a multilayer actuator with delamination of the layer structure, excited by the measuring signal according to FIG. 3a)-3c) Exemplary curve of the electrical impedance of an intact actuator as a function of the frequency f, excited by the measuring signal according to FIG. 3a); d) Exemplary curve of the electrical impedance of an actuator with delamination as a function of the frequency f, excited by the measuring signal according to FIG. 3a)

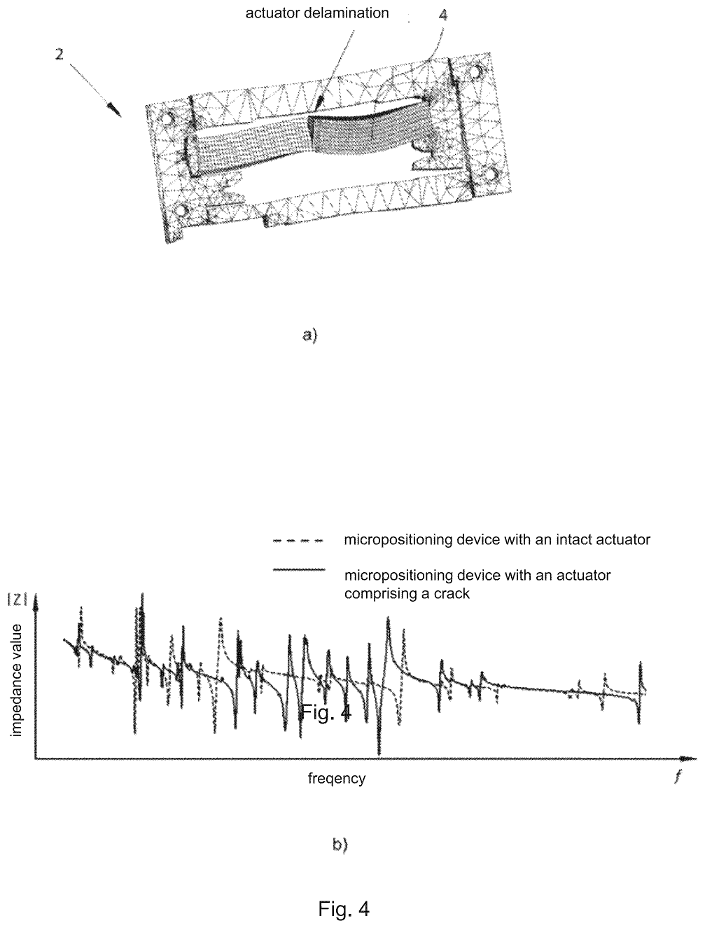

FIG. 4: a) FEM model of the positioning unit according to the invention with an actuator having a delamination of the layer structure, excited by the measuring signal according to FIG. 3a); b) exemplary course of the magnitude of the electrical impedance |Z| of the positioning unit as a function of frequency with an intact and a actuator comprising a crack as a function of f, excited by the measuring signal according to FIG. 3a)

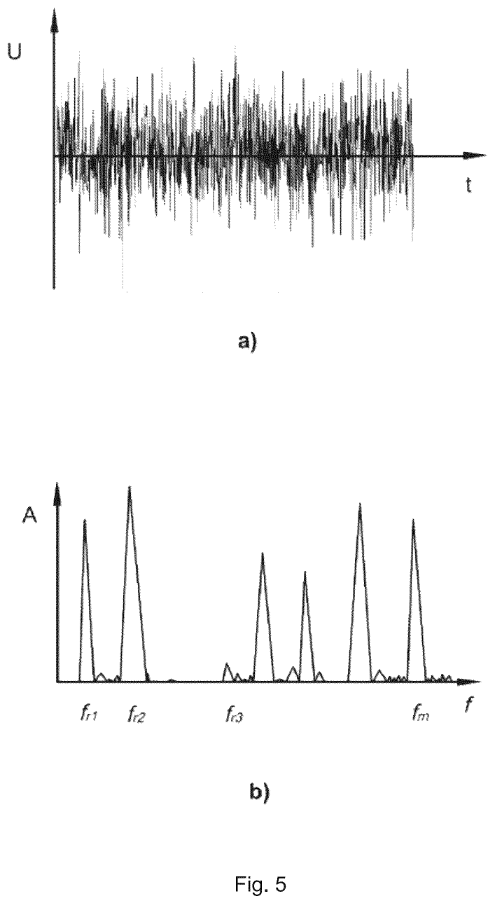

FIG. 5: a) white noise signal; b) amplitude spectrum of the positioning unit excited by a measurement signal generator with the white noise signal according to FIG. 5a)

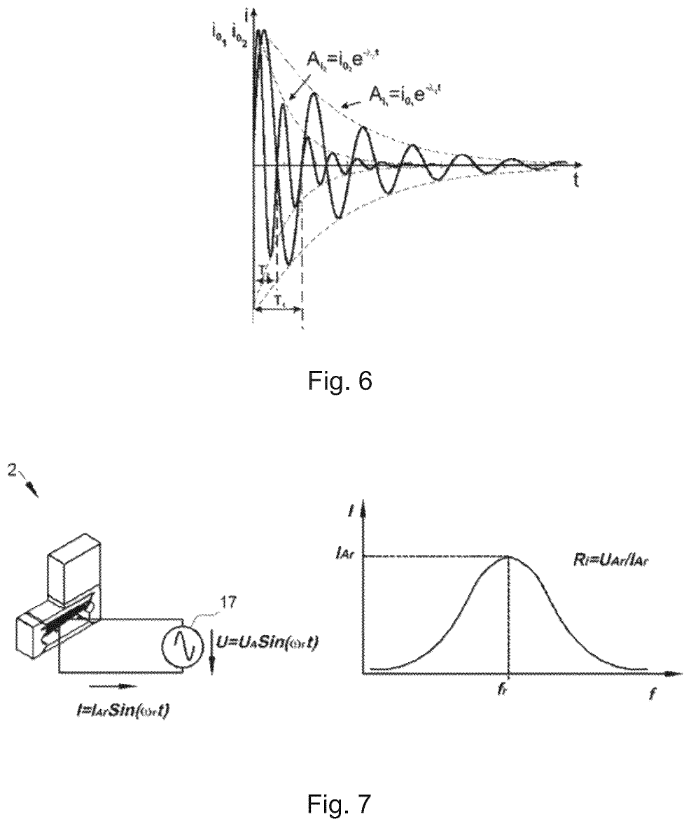

FIG. 6: Example current decay curves of the positioning unit with an intact and a delaminated actuator.

FIG. 7: Current resonance curve of the positioning unit to explain the measurement of the loss resistance.

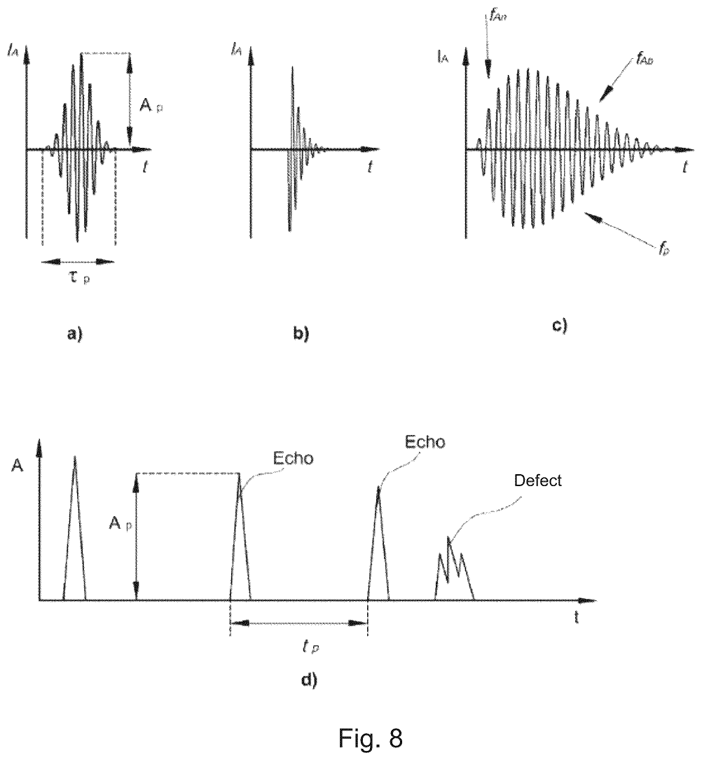

FIGS. 8a)-8c): Different forms of ultrasonic pulses; d) Echo of ultrasonic pulses.

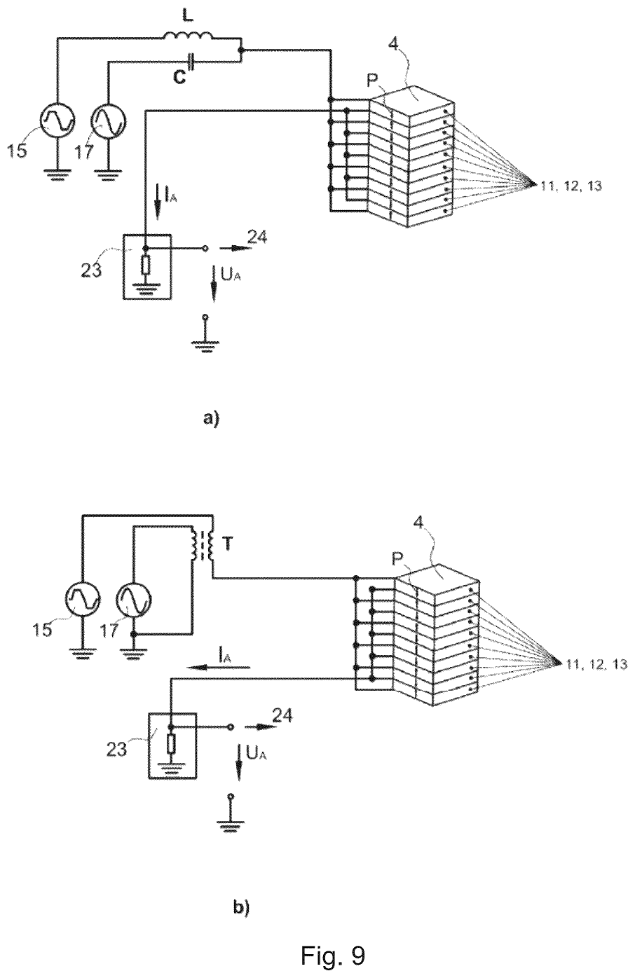

FIG. 9: Schematic diagram of a possible circuit implementation of simultaneous normal operation of an actuator of a positioning unit of a positioning device according to the invention with the resonance analysis mode, where 9a) illustrates the connection of a power output stage and a current or voltage amplifier to the actuator via an inductor and via a capacitor, respectively, while 9b) shows the connection of a power output stage to the actuator via a transformer.

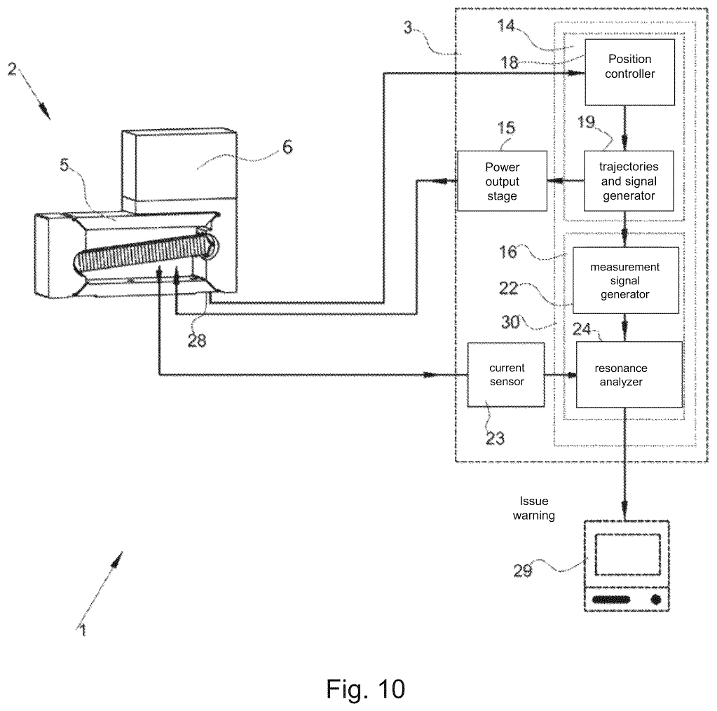

FIG. 10: Positioning device with a common power stage and a simultaneous arrangement of the measurement signal generator, the resonance analyzer and the presetting-regulation controller in the same integrated circuit.

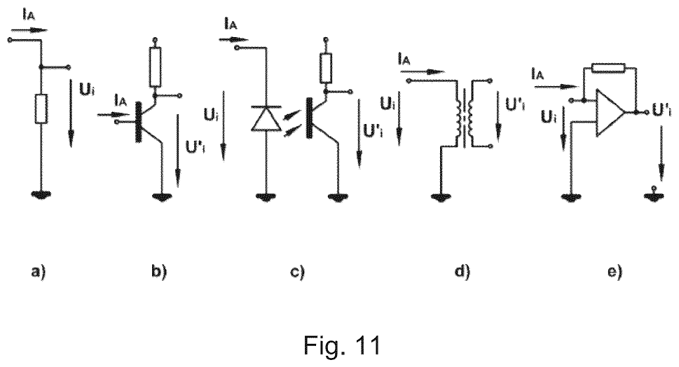

FIGS. 11a)-11e): Principle structure of a current sensor in different versions.

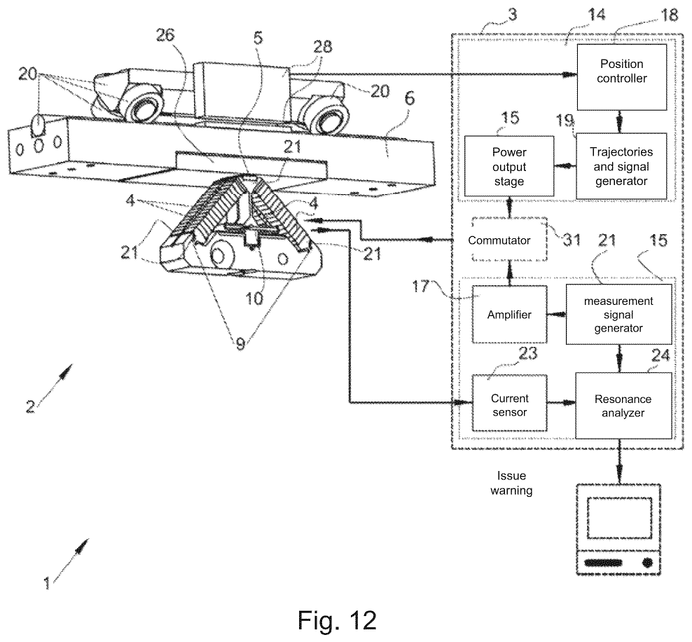

FIG. 12: Schematic representation of a positioning unit with several multilayer actuators, in which the coupling between the drive element and the element to be positioned is realized via a friction contact.

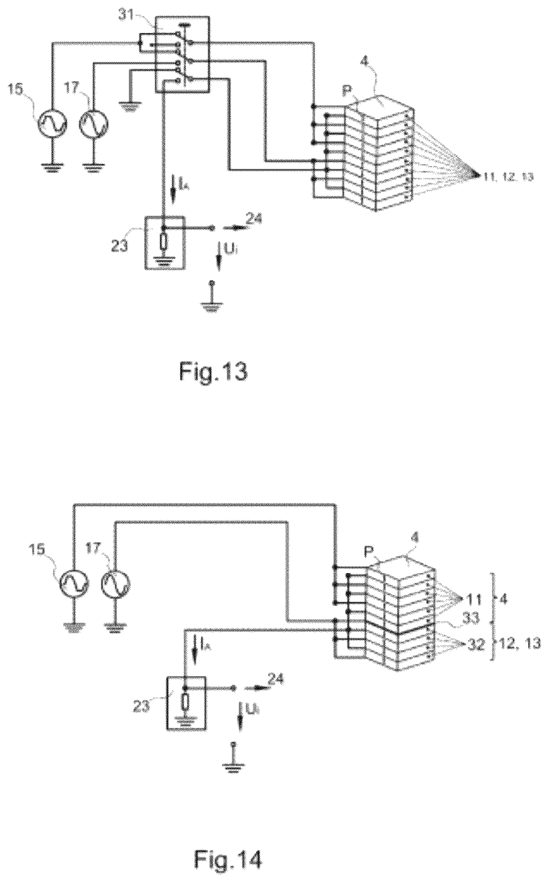

FIG. 13: Actuator with area-wise utilization of the layers to realize a generator and a receiver.

FIG. 14: Exemplary realization of a generator or a receiver as a part connected to the actuator but not acting as an actuator.

FIG. 1 schematically illustrates a positioning device 1 according to the invention for detecting defects in a positioning unit 2 driven by an actuator 4.

The positioning device 1 comprises, in addition to the positioning unit 2, the controller 3. The positioning unit 2 comprises, in addition to a single piezoelectric and multilayer actuator 4, which is designed to have, in addition to its movement or drive function, the function of a generator 12 and a receiver 13 of acoustic ultrasonic waves, a drive element 5 moved or driven by the actuator 4, which is coupled to an element 6 to be positioned by a fixed connection. In addition, the positioning unit 2 includes a position sensor not shown in FIG. 1.

The actuator 4 is supported at its two ends on retaining elements 21, which are connected to a frame surrounding the actuator via solid-state joints 9, so that the drive element 5 integrated in the frame is coupled to the actuator 4 via the solid-state joints 9 and movements or deformations of the actuator 4 can be transmitted to the drive element 5.

The piezoelectric actuator 4 is composed of several layers 11, each layer consisting of two electrodes and a polarized piezoelectric material arranged in between. Possible polarization directions of the individual layers are indicated by the arrows P in FIG. 1.

The controller 3, which has the function of controlling or regulating the actuator 4 or the positioning unit 2, exciting the generator 12 with a measurement signal, and processing the signal coming from the receiver 13, comprises a presetting-regulation controller 14, a defect analysis device 16, by which the generator 12 is excited and the signal from the receiver 13 is recorded and analyzed, and optionally a commutator 31. In the commutator 31, switching takes place between an actuator 4 actuating operation and a sensing operation in which the actuator or a portion thereof acts as a generator 12 and a receiver 13, respectively. In addition, the controller 3 may interface with a computer 29 having a display screen on which the defect analysis can be performed visually by an operator.

The presetting-regulation controller 14 includes a power output stage 15 for the actuator 4, a trajectory and signal generator 19, a controller 18 for the position and optionally for the speed and acceleration of the positioning unit 2.

The defect analysis device 16 includes a current-voltage amplifier 17 for the generator 12, a measurement signal generator 22, a current sensor 23 for the signal generated by the receiver 13, and a resonance analyzer 24.

FIG. 2 illustrates a schematic diagram of a preferred embodiment of the piezoelectric actuator 4 with a generator 12 and a receiver 13. The layers 11 of the actuator 4 are formed by conductive metallized surfaces as well as a polarized piezoelectric material located between them. In one possible variant of the electrical polarization of the layers 11, polarization vectors of the adjacent layers are directed opposite to each other. The vector of electrical polarization is marked with an arrow P in FIG. 2 as well as in the corresponding other figures. The layers 11 are electrically parallel and mechanically connected in series.

FIG. 3a) illustrates the voltage U_{MG} of the measuring signal generator with a variable frequency, while FIG. 3b) illustrates the FEM model of a multilayer actuator 4 with a delamination of the layer structure. FIG. 3c) illustrates an exemplary curve of the electrical impedance of an intact actuator as a function of the frequency f. Here, resonances of three oscillation modes of the actuator 4 can be seen, namely the first, the third and the fifth longitudinal mode. FIG. 3d) illustrates an exemplary curve of the electrical impedance of the actuator 4 with delamination as a function of the frequency f. Here, additional resonances can be seen which have arisen due to the delamination.

FIG. 4a) shows the FEM model of a positioning unit 2 with an actuator 4 according to FIG. 1, which has a delamination of the layer structure. FIG. 4 b) illustrates an exemplary curve of the magnitude of the electrical impedance of a positioning unit 2 as a function of frequency with an intact and a cracked actuator 4 as a function of f. Due to the delamination in the actuator 4, the curves of the impedance magnitude differ substantially. Resonances that were present when the actuator was intact have disappeared, and new resonances due to the delamination have been added.

FIG. 5a) illustrates the amplitude spectrum of the positioning unit excited by white noise, while FIG. 5b) corresponds to the current flowing through the actuator 4 and the receiver 13, respectively, subjected to a Fourier transformation and recorded as a function of frequency.

FIG. 6 illustrates exemplary current decay curves of a positioning unit 2 with an intact and a delaminated actuator. The decay curve of the positioning unit with a damaged actuator with the amplitude decay function Aᵢ₂ decays faster than the Aᵢ₁ with the intact actuator due to the changed resonant frequency and the decay constant λ₂. Due to the delamination, the oscillation period T2 has decreased for the amplitude decay function Aᵢ₂.

FIG. 7 illustrates a current resonance curve of a positioning unit 2 according to FIG. 1, which is excited in one of its resonances by a sinusoidal measurement signal of amplitude U_{Ar}. The current I_{Ar} flowing through the receiver 13 is measured. Rᵢ=U_{A}/I_{Ar} is determined by the defect analysis device and compared with a previously measured value. When a defined deviation occurs, a warning is output.

FIG. 8 illustrates different shapes of the ultrasonic pulses emitted by a generator 12 and of the ultrasonic pulses reflected by the positioning unit 2 and detectable by the receiver 13. According to FIG. 8a), the ultrasonic pulses can have an exponential rise as well as an exponential decay, according to FIG. 8b) they can have only an exponential decay, or according to FIG. 8c) they can also have different rise as well as decay functions. The ultrasonic pulses are characterized by their amplitude A_{P}, frequency f_{P}, duration τ, rise and decay functions f_{An}, f_{Ap} and runtime tₚ.

FIG. 9 illustrates the principle structure of a possible circuit implementation for simultaneous normal operation of the positioning device or positioning unit with a resonance analysis mode. According to FIG. 9a), the power output stage 15 is connected to the actuator 4 via an inductance L. The current or voltage amplifier 17 excites the actuator 4 or the generator 12 via a capacitance C. On the one hand, the capacitance C isolates the power output stage 15 from the amplifier 17 in terms of direct current. On the other hand, the inductance L isolates the amplifier 17 from the power output stage 15 in terms of alternating current. According to FIG. 9b), the power output stage 15 is connected to the actuator 4 via the secondary winding of the transformer T. The current or voltage amplifier 17 excites the generator 12 via the primary winding of the transformer T. The transformer T isolates the power output stage 15 from the amplifier 17 in terms of direct current.

FIG. 10 illustrates a positioning device 1 with a positioning unit 2 according to FIG. 1, in which the same power output stage 15 used to drive the multi-layer actuator by the open-loop controller is used by the defect analysis device as the output voltage or current amplifier for the measurement signal generator 22. In this case, the power output stage 15 has sufficient bandwidth to meet the requirements for generating ultrasonic acoustic waves by the actuator or generator 12. This saves the cost and space of installing a separate amplifier.

FIG. 10 further illustrates an embodiment of the positioning device 1, in which the measurement signal generator 22 as well as the resonance analyzer 24 are housed in the same integrated circuit 30 as the closed-loop control controller 14.

FIG. 11 illustrates the principle structure of possible circuits for the first processing of the electrical signal coming from the receiver 13 in the form of a current or a voltage. According to FIG. 11a) the current I_{A} coming from the receiver 13 can be represented by the voltage Uᵢ, by means of a resistor. By means of the circuit in FIG. 11 b), the current I_{A} coming from the receiver 13 is converted into a voltage U′ᵢ by means of a transistor. In FIG. 11c), the current I_{A} coming from the receiver 13 is mapped into a voltage U′ᵢ with the aid of an optocoupler. In the circuit arrangement shown in FIG. 11 d), the current I_{A} coming from the receiver 13 or the voltage U_{A} is converted into a voltage U′ᵢ with the aid of a transformer. The circuit arrangement shown in FIG. 11 e) converts the current I_{A} or the voltage U_{A} coming from the receiver 13 with the aid of an operational amplifier into the voltage U_{V}.

FIGS. 1, 7 and 10 illustrate a schematic diagram of a positioning unit 2 in which a single multilayer piezoelectric actuator 4, which also forms the generator 12 as well as the receiver 13, is arranged between solid-state joints 9.

FIG. 12 shows a schematic representation of a positioning unit 2 with several, i.e. a total of four, multilayer piezoelectric actuators 4, each of the actuators being arranged in or between solid-state joints 9. The ends of the respective actuator 4 rest against retaining elements 21. The transmission of motion from the drive element 5 of the actuator 4 to the element 6 to be positioned takes place via a frictional contact, in which the drive element 5 comes into or is in frictional contact with a friction rail 26 of the element 6 to be positioned. The element 6 to be positioned is here linearly mounted and guided via a guide device 20. A position sensor 28 is used to detect the position of the element 6 to be positioned.

FIG. 13 illustrates an actuator 4 in multilayer design, in which only some layers 11 are used for the realization of the generator 12 and receiver 13. It is conceivable to use a number of layers for the realization of the generator 12 that is different from the number of layers used for the realization of the receiver 13. In the upper position of the commutator 31, the layers of the actuator are connected to the power output stage 15. The actuator is in the actuating or drive mode. By switching to the lower position, the layers of the actuator intended for the function of a generator or the function of a receiver are connected to the power output stage and thus form the generator 12 or the receiver 13, respectively. The actuator current is converted into the voltage Uᵢ, by the current sensor 23 and further processed by the resonance analyzer 24.

FIG. 14 illustrates an exemplary realization of the generator 12 or receiver 13 as a part connected to the actuator, but not itself acting actuatorily, i.e. performing a deformation when an electric voltage is applied. The layers of the generator 12 and receiver 13 of ultrasonic acoustic waves have polarization directed opposite to each other. The generator 12 and the receiver 13 are connected to the remaining part of the actuator by an acoustic connection with a low acoustic resistance, so that the ultrasonic acoustic waves are not substantially reflected or attenuated by the boundary layer. Such a connection can be realized, for example, by sintering the actuator to the generator or receiver. Similarly, it is possible to connect the components in a furnace by easily melting glass or a similar hard material.

The mode of operation of the positioning device 1 according to the invention or the method according to the invention is explained with reference to FIG. 1. In a first step, an etalon measurement is carried out. For this purpose, during the initial start-up of the intact positioning unit 2, its resonance image is recorded by the defect analysis device 16. In this process, the piezoelectric actuator 4, in its function as a generator of acoustic ultrasonic waves 12, is acted upon by the measurement signal generator 22 with an electrical measurement signal. The measurement signal represents an electrical voltage with a frequency f. The measurement signal voltage is amplified by the current-voltage amplifier 17. The measurement signal voltage is amplified by the current-voltage amplifier 17 and passed on to the generator 12 via the commutator 31. This excites the generator 12 and generates ultrasonic waves which are radiated into the positioning unit. The propagation of the ultrasonic waves excites resonant vibrations in components of the positioning unit as well as in the actuator itself. These resonance oscillations in turn generate acoustic ultrasonic waves which reach the receiver 13 together with the reflected ultrasonic waves and are detected by it in the form of a current change.

The current I_{A} from the receiver 13 reaches the current sensor 23 of the defect analysis device, is converted by it into a voltage Uᵢ, and is passed on to the defect analysis device 16. In the defect analysis device, the current I_{A} or its image, the voltage Uᵢ, the voltage U_{MS} coming from the measurement signal generator 22, and the phase angle value φ between the current I_{A} and the voltage U_{MS} are recorded, stored, and a resonance image of the positioning unit is created from them.

The positioning unit then starts to operate in order to perform the intended positioning tasks. Here, the trajectory and signal generator 19 controls the actuator 4 with a control signal, amplified by the power output stage 15 or conducted via the commutator 31. The actuator brings the drive element 5 and the element to be positioned, which is coupled to it, into a positioning movement. The positioning can be controlled by the controller 18 with the aid of the position sensor 28.

After a certain operating time, a status or defect diagnosis of the positioning unit is carried out. For this purpose, a measurement is carried out in accordance with the first step of the method according to the invention. An electrical measurement signal is applied to the generator 12 by the measurement signal generator 22. As a result, the generator 12 is excited and generates ultrasonic waves which are radiated into the positioning unit. As a result of the propagation of the ultrasonic waves, resonance oscillations are excited in components of the positioning unit as well as in the actuator itself. These resonance oscillations in turn generate acoustic ultrasonic waves which reach the receiver 13 together with the reflected ultrasonic waves and are detected by it in the form of a change in current.

The current I_{A} from the receiver 13 reaches the current sensor 23 of the defect analysis device, is converted by it into a voltage Uᵢ, and is passed on to the defect analysis device 24. In the defect analysis device, the current I_{A} or its image, the voltage Uᵢ, the voltage U_{MS} coming from the measurement signal generator 22, and the phase angle value φ between the current I_{A} and the voltage U_{MS} are recorded, stored, and a resonance image of the positioning unit is created from them.

In a subsequent process step, the resonance analyzer 24 compares the currently created resonance image of the positioning unit with the resonance image of the intact positioning unit. The presence of a new, the change or the absence of previously existing mechanical resonances is determined. For this purpose, appropriate algorithms are implemented in the resonance analyzer, for example those of neural networks. If a defined deviation in the current measurement from the etalon measurement is detected, which indicates an imminent failure of the positioning unit, a warning is issued by the defect analysis device.

Various advantageous methods can be used for creating the resonance image of the positioning unit. For example, the positioning unit 2 can be supplied with an electrical measuring signal from the measuring channel generator 22, which represents an electrical voltage with a variable frequency f (see FIGS. 3 and 4). The frequency f changes here from an initial to a final value. In the resonance analyzer 24, the current I_{A} flowing through the receiver 13 or its image, the voltage Uᵢ the voltage U_{MS} coming from the measuring signal generator 22, and the phase angle value @ between the current I_{A} and the voltage U_{MS} are recorded as a function of the frequency f. From the stored series of measurements, for the purpose of detecting resonances of the positioning unit, the function of the impedance |Z|=U_{A}/I_{A} is formed by the frequency. From the frequency-dependent course of the impedance, the resonance analyzer creates the resonance image of the positioning unit and generates a defect prediction or diagnosis.

Furthermore, the positioning unit 2 can be supplied with an electrical measuring signal from the measuring channel generator 22, which represents an electrical voltage with a certain frequency f. The resonance mapping is carried out on the basis of parameters of individual resonances (see FIGS. 6 and 7). The resonance mapping is performed on the basis of parameters of individual resonances (see FIG. 6 and FIG. 7).

In another advantageous method, the measuring channel generator 22 applies an electrical measuring signal of short duration and at least a certain frequency f to the positioning unit 2. The resonance image of the positioning unit is created based on parameters of the reflected ultrasonic waves (see FIG. 8). In doing so, the resonance analyzer records and analyzes the duration of the reflected pulse or pulses, the amplitude, the transit time or the shape.

In a manual creation of the resonance image of the positioning unit and its visual analysis, the data is output from the defect analysis device to the computer 22 having a display screen and analyzed by an operator.

### LIST OF REFERENCE SIGNS

1 positioning device
2 positioning unit
3 controller
4 actuator
5 driving element
6 element to be positioned
9 solid joint
11 piezoelectric layers (of actuator 4)
12 generator of acoustic ultrasonic waves
13 receiver of acoustic ultrasonic waves
14 control regulation
15 controller power output stage
16 defect analysis device
17 current or voltage amplifier
18 controller of position, speed or acceleration
19 trajectory and signal generator
20 guidance device
21 holding element (of actuator 4)
22 measurement signal generator
23 current sensor
24 resonance analyzer
25 friction rail
26 position sensor
29 computer
30 integrated circuit (e.g. FPGA, DSP)
31 electronic commutator
32 layers of the generator and of the receiver of ultrasonic acoustic waves
33 connecting layer of the actuator with the generator and receiver of ultrasonic acoustic waves

1-26. (canceled)

27. A positioning device, comprising a positioning unit with a piezoelectric actuator, a drive element movable by the actuator and provided for coupling to an element to be positioned, and a controller, characterized in that the positioning device comprises a defect analysis device for detecting defects in the positioning unit, wherein in the case that the positioning unit comprises a single actuator, the actuator comprises a generator and a receiver of acoustic ultrasonic waves and in the case that the positioning unit comprises a plurality of actuators, at least one of the actuators comprises at least one generator of ultrasonic acoustic waves and at least another one of the actuators comprises at least one receiver of ultrasonic acoustic waves, and wherein the defect analysis device comprises a measurement signal generator for generating an electric voltage for exciting the or a generator and a resonance analyzer for analyzing an electric signal generated by the or a receiver.

28. The positioning device according to claim 27, characterized in that the measurement signal generator is configured to cause the frequency of the electrical sinusoidal voltage to change periodically from an initial to a final value.

29. The positioning device according to claim 27, characterized in that the defect analysis device comprises a broadband linear or clocked output voltage or current amplifier.

30. The positioning device according to claim 27, characterized in that the controller comprises an output stage for driving the positioning unit, the same output stage also serving to electrically supply the measurement signal generator.

31. The positioning device according to claim 27, characterized in that the defect analysis device comprises a white noise generator.

32. The positioning device according to claim 27, characterized in that the controller comprises a position controller and a trajectory and signal generator, wherein the position controller or the trajectory and signal generator are realized by means of an integrated circuit, and the measurement signal generator and the resonance analyzer are realized as a program module in the same integrated circuit.

33. The positioning device according to claim 27, characterized in that the resonance analyzer comprises a data interface to a display screen for a visual control of a resonance image.

34. The positioning device according to claim 27, characterized in that the defect analysis device comprises a current sensor for detecting an electrical signal generated by a receiver, wherein a resistor, a transistor, a transformer, an optocoupler or an operational amplifier is used for detecting a current.

35. The positioning device according to claim 27, characterized in that an actuator is designed as a multilayer piezoelectric actuator.

36. The positioning device according to claim 27, characterized in that an actuator is arranged between solid-state joints, and the transmission of a deflection of the actuator to the drive element is realized without friction by elastic deformation of the solid-state joints.

37. The positioning device according to claim 27, characterized in that a generator or a receiver forms part of an actuator and has no actuating function.

38. The positioning device according to claim 37, characterized in that the part of an actuator forming a generator or a receiver is connected to the remaining part of the same actuator by an acoustic connection with a low acoustic resistance.

39. The positioning device according to claim 27, characterized in that a generator is formed in one actuator and a receiver is formed in another and spaced actuator.

40. A method for operating the positioning device according to claim 27, wherein a generator is periodically supplied with an electrical measuring signal of the measuring signal generator in the form of an electrical alternating voltage, and mechanical resonances of the positioning unit are periodically picked up with a receiver, and by means of the resonance analyzer the emergence of new or the disappearance or the change of previously existing resonances are detected and analyzed for predicting or detecting defects in the positioning unit.

41. The method according to claim 40, characterized in that the frequency of the measurement signal is changed from an initial to a final value, and thereby the current value flowing through a receiver and the phase angle value between the current and the voltage are measured in the form of a dependence on the frequency and recorded together with the voltage, and from the series of measurements for detecting resonances the function of the impedance |Z| is formed from the frequency, and from the impedance the presence of new or the change or absence of previously detected mechanical resonances is determined.

42. The method according to claim 40, characterized in that the function of the impedance amount |Z| from the frequency with the phase angle is represented in a Nyquist diagram, from which the presence of new or the change or the absence of previously detected mechanical resonances is determined.

43. The method according to claim 40, characterized in that the initial frequency value of the measurement signal is equal to the lowest detectable resonance frequency value of an actuator and the final frequency value of the measurement signal is equal to the resonance frequency value of the highest measurable resonance of an actuator, wherein both the lowest resonance frequency value and the highest resonance frequency value belong to the different types of ultrasonic acoustic waves.

44. The method according to claim 40, characterized in that the initial frequency value of the measurement signal is equal to the lowest resonance frequency value of an actuator determined by its length, and the final frequency value of the measurement signal is equal to twice the resonance frequency value determined by half the actuator length.

45. The method according to claim 40, characterized in that the frequency of the measurement signal is logarithmically varied from the initial to the final value.

46. The method according to claim 40, characterized in that the measurement signal is white noise and the current flowing through a receiver is measured and recorded, the measurement results being subjected to a Fourier transformation or a discrete or a fast Fourier transformation for the purpose of detecting resonances that are newly emerging or have disappeared.

47. The method according to claim 40, characterized in that the frequency value of the measurement signal is equal to a measurable resonance frequency value of an actuator, said resonance frequency belonging to the various types of ultrasonic acoustic waves, and wherein after a short excitation of a generator at the resonance frequency, the decay of the positioning unit is recorded via a receiver and thereafter, for the purpose of detecting a resonance change, the recorded decay curve is compared with a decay curve recorded at an earlier time.

48. the method according to claim 40, characterized in that the frequency value of the measurement signal is equal to a measurable resonance frequency value of the positioning unit, wherein after a short excitation of a generator the decay behavior of the positioning unit is recorded for the purpose of detecting a resonance change and compared with a decay behavior recorded at an earlier time.

49. The method according to claim 40, characterized in that the frequency value of the measurement signal is equal to at least one measurable resonance frequency value of the positioning unit, wherein during the excitation of a generator for the purpose of detecting at least one resonance change, the internal resistance Rᵢ=U_{A}/I_{Ar} of the positioning unit is determined and compared with a value of the internal resistance of the positioning unit recorded at an earlier time.

50. The method according to claim 40, characterized in that the frequency value of the measurement signal is substantially equal to a measurable resonance frequency value of the positioning unit, and in that during or after a short excitation of a generator the reflected pulse is picked up by a receiver, parameters of the reflected pulse being recorded for detecting a resonance change and being compared with parameters recorded at an earlier time.

51. The method according to claim 40, characterized in that the detection of resonances and the defect analysis are performed in the normal operating mode of the positioning unit.

52. The method according to claim 40, characterized in that the analysis of the recorded resonance image is performed visually by the operator.
